(19) United States
(12) Patent Application Publication
(10) Pub. No.: US 2025/0254787 A1
(43) Pub. Date: Aug. 7, 2025

(54) PCB STRUCTURE WITH HEAT DISSIPATION FUNCTION

(71) Applicant: Taiwan Ruomei Technology Corp., Taipei City (TW)

(72) Inventors: Hou-Yu Lee, Taipei City (TW); Si-Han Lin, Taipei City (TW)

(73) Assignee: Taiwan Ruomei Technology Corp., Taipei City (TW)

(21) Appl. No.: 19/025,904

(22) Filed: Jan. 16, 2025

(30) Foreign Application Priority Data
Feb. 7, 2024 (TW) 113105147

(51) Int. Cl. H05K 1/02

(52) U.S. Cl. CPC H05K 1/0206; H05K 2201/2081

(57) ABSTRACT

A printed circuit board (PCB) structure with heat dissipation function, includes: at least one substrate, which includes a first substrate including a first primer material and a first electronic conductive layer disposed on the first primer material; and a solder mask layer, disposed on the electronic conductive layer; wherein when the at least one substrate includes the first substrate and a second substrate, the PCB structure further includes an adhesive insulation layer connected between the first substrate and the second substrate. At least one of the material compositions of the solder mask layer and the adhesive insulation layer, includes an aluminum oxide-boron nitride-fullerene composite material, to transmit heat from the substrates to the outside of the substrate by radiation heat transfer.

### CROSS REFERENCE

The present invention claims priority to TW113105147 filed on Feb. 7, 2024.

### BACKGROUND OF THE INVENTION

### Field of Invention

The present invention relates to a printed circuit board (PCB) structure with a heat dissipation function, which is capable of transferring waste heat from the circuit board to the outside by heat radiation.

### Description of Related Art

Traditional circuit board cooling technology usually utilizes metal cooling fins to transfer heat generated from the working circuit board, into the outside of the circuit board. In this way, the heat dissipation from the circuit board, is mainly achieved by heat conduction between the circuit board and the cooling fins, and by heat convection between the cooling fins and neighboring air for the heat dissipation. When the heat dissipation requirement is more intense, the number of cooling fins correspondingly increases to occupy more space for disposing these cooling fins. This cooling design is very space-consuming, and the necessary power to blow the high-temperature air passing by the cooling fins becomes higher.

### SUMMARY OF THE INVENTION

In view of the aforementioned technical needs, the present invention provides a PCB structure with heat dissipation function, which includes: at least one substrate, which includes a first substrate with a first primer material and a first electronic conductive layer disposed on the first primer material; and a solder mask layer, disposed on the first electronic conductive layer; wherein when the at least one substrate includes the first substrate and a second substrate, the PCB structure further includes an adhesive insulation layer connected between the first substrate and the second substrate. At least one of the material compositions of the solder mask layer and the adhesive insulation layer, includes an aluminum oxide-boron nitride-fullerene composite material, to transmit heat from the substrates to the outside of the substrate by radiation heat transfer.

In one embodiment, the first electronic conductive layer covers a top surface of the first primer material, or the first electronic conductive layer covers the top surface and a bottom surface of the first primer material opposite to the top surface, wherein the solder mask layer covers the first electronic conductive layer.

In one embodiment, the aluminum oxide-boron nitride-fullerene composite material includes plural micro-composite particles, wherein the aluminum oxide is disposed at the center of each of the micro-composite particles, and the aluminum oxide is encircled by plural sandwich structures in the micro-composite particle. Each of the sandwich structures is formed in a sequence of boron nitride, fullerene.

In one embodiment, the particle sizes of the micro-composite particles preferably range between 0.01 μm and 60 μm.

In one embodiment, the material of the adhesive insulation layer includes the aluminum oxide-boron nitride-fullerene composite material, and the first primer material is made of a high thermal radiation transmissive material, wherein the thermal radiation from the adhesive insulation layer penetrates into the first primer material; or the first substrate includes a thermal radiation-permeable section, and the thermal radiation from the adhesive insulation layer passes through the thermal radiation-permeable section.

In one embodiment, the through-holes include two interconnected through-holes, or the through-holes are in a disposition formation of a through-hole matrix.

In one embodiment of the thermal radiation-permeable section, the first substrate includes at least one through-hole, and the thermal radiation from the adhesive insulation layer passes the through-holes into the outside of the PCB structure.

In one embodiment, the material of the primer material, includes epoxy resin, glass fiber nonwoven, polyester fiber, bake lite, or polyester material.

In one embodiment, a weight ratio of the aluminum oxide-boron nitride-fullerene composite material in at least one material composition of the solder mask layer and the adhesive insulation layer, preferably ranges from 2% to 30%, with an optimal weight ratio being substantially 10%.

The objectives, technical details, features, and effects of the present invention can be better understood with regard to the detailed description of the embodiments below, with reference to the associated drawings.

### BRIEF DESCRIPTION OF THE DRAWINGS

FIGS. 1 and 2 show two cross-section views of PCB structures with heat dissipation function according to two embodiments of the present invention.

FIG. 3 shows a schematic diagram of a composite particle of aluminum oxide-boron nitride-fullerene composite material according to one embodiment of the present invention.

FIG. 4 shows a schematic diagram of a sandwich structure in the aluminum oxide-boron nitride-fullerene composite material according to one embodiment of the present invention.

FIG. 5 shows a schematic diagram of the molecular structure of a fullerene in a long capsule-like shape according to one embodiment of the present invention.

FIGS. 6 and 7 show two cross-section views of a PCB structure with heat dissipation function according to two embodiments of the present invention.

### DESCRIPTION OF THE PREFERRED EMBODIMENTS

The technical wordings/terms in this specification are based on customary understanding in the art. When any wording/term is described or defined in this specification, the interpretation of the term/wording is primarily based on the description or the definition set forth in this specification. Each embodiment of the present invention includes one or more technical features. To the extent possible, a person having ordinary knowledge in the art may combine or modify these features, whether in whole or in part, within the scope and spirit of this invention.

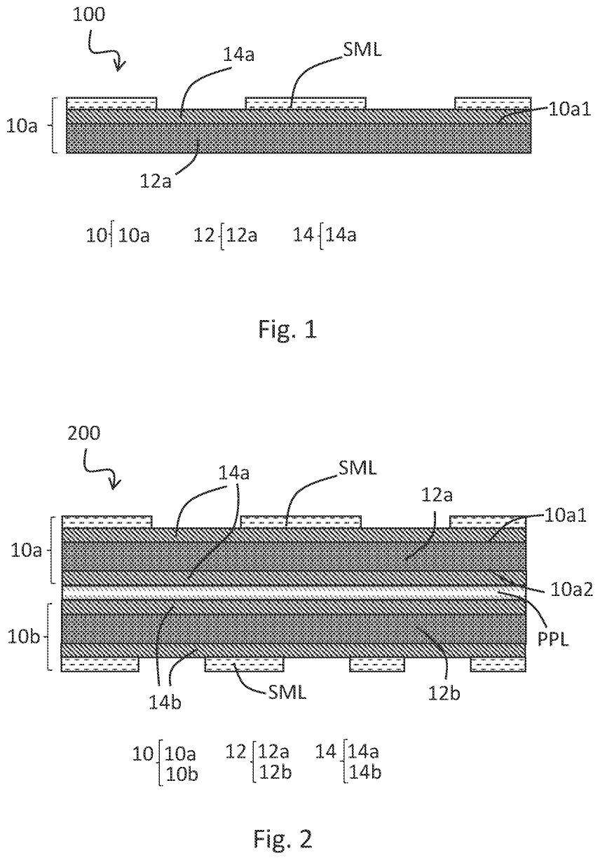

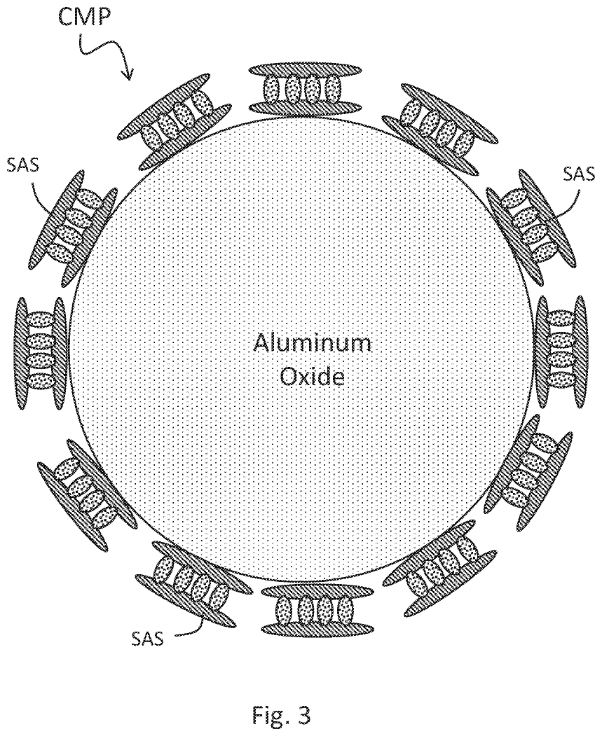

In view of the aforementioned technical requirements, as shown in FIGS. 1 and 2, the present invention provides a PCB structure with heat dissipation function 100 (or, 200), which includes: at least one substrate 10, each substrate 10 including a primer material 12 and an electronic conductive layer 14, wherein the at least one substrate 10 includes a first substrate 10a with a first primer material 12a, and a first electronic conductive layer 14a of the electronic conductive layer 14 is disposed on the first primer material 12a; and a solder mask layer SML (In FIG. 1, the substrate 10 includes a first substrate 10a, the primer material 12 includes the first primer material 12a, and the electronic conductive layer 14 includes the first electronic conductive layer 14a. In FIG. 2, the substrate 10 includes the first substrate 10a and a second substrate 10b, the primer material 12 includes the first primer material 12a and a second primer material 12b, and the electronic conductive layer 14 includes the first electronic conductive layer 14a and a second electronic conductive layer 14b). The solder mask layer SML, is disposed on the electronic conductive layer 14 (the first electronic conductive layer 14a, or both of the first electronic conductive layer 14a and the second electronic conductive layer 14b). When the at least one substrate 14 includes the first substrate 10a and the second substrate 10b (e.g., the PCB structure shown in FIG. 2), the PCB structure with heat dissipation function 200 includes an adhesive insulation layer (Prepreg layer) PPL, for being adhered between the first substrate 10a and the second substrate 10b. At least one of the material compositions of the solder mask layer SML and the adhesive insulation layer PPL, includes an aluminum oxide-boron nitride-fullerene composite material (FIG. 3 shows a micro-composite particle CMP of the aluminum oxide-boron nitride-fullerene composite material, which is described in detail in the subsequent embodiments). The aluminum oxide-boron nitride-fullerene composite material can effectively transmit heat from the substrate 10 to the outside of the substrate 10 by radiation heat transfer. The PCB structures 100 and 200 provided by the present invention, substantially focus on how to enhance the radiation heat dissipation by the aluminum oxide-boron nitride-fullerene composite material. The existing circuit board design can be partially modified to implement the technology of the present invention, to provide a high radiation heat dissipation effect. For example, the aluminum oxide-boron nitride-fullerene composite material can be mixed in the existing material of the solder mask layer SML in the PCB structures 100 and 200, or mixed in the existing material of the adhesive insulation layer PPL, to enhance the radiation heat dissipation capability of the PCB structure.

Particularly, the solder mask layer SML may not be limited to one side of the substrate (see FIG. 2). For example, when there is an electrical electronic conductive layer 14 (e.g., a first electronic conductive layer 14a and a second electronic conductive layer 14b) on both sides of the PCB structure 100, the solder mask layer SML can be a two-layer structure, on both of the first electronic conductive layer 14a and the second electronic conductive layer 14b.

The traditional circuit boards do not focus on the high efficiency thermal radiation to improve the cooling, and most of the traditional circuit boards rely on cooling fins to have effective heat conduction, which occupy a lot of space for disposing the cooling fins. Therefore, the traditional design limits its thermal radiation effect. Importantly, the absolute temperature T in the thermal radiation formula P=εσAT⁴ exhibits a quadratic form equation, so that the formula value change of the thermal radiation effect corresponds to a quadratic temperature dependence (high order temperature term), which can, in certain scenarios, be significantly more effective at cooling than the linear temperature dependence of thermal conduction. In the formula, ε denotes the surface emissivity of the object, and σ denotes the Stefan-Boltzmann constant, and A denotes the surface area of the object. When the emissivity of the surface of the object is high, the effect of thermal radiation for cooling can be considerable. Moreover, the convection cooling in a high-temperature working environment poses a challenge, especially when relying on convection with a limited temperature difference. Under such conditions, the thermal radiation cooling remains highly effective, even at elevated temperatures.

In one embodiment, the first electronic conductive layer 14a covers a top surface 10a1 of the first primer material 12a (FIG. 1), or covers the top surface 10al and a bottom surface 10a2 (FIG. 2) of the first primer material 12a opposite to the top surface 10a1. The electronic conductive layer 14 can be used for signal transmission circuits, grounding circuits, a physical shock buffering area for EMS (Electromagnetic Sensibility), dissipating heat, etc. The solder mask layer SML covers the electronic conductive layer 14 to avoid unnecessary short-circuit connection when tinning the electronic conductive layer 14, and to protect the electronic conductive layer 14 from oxidation.

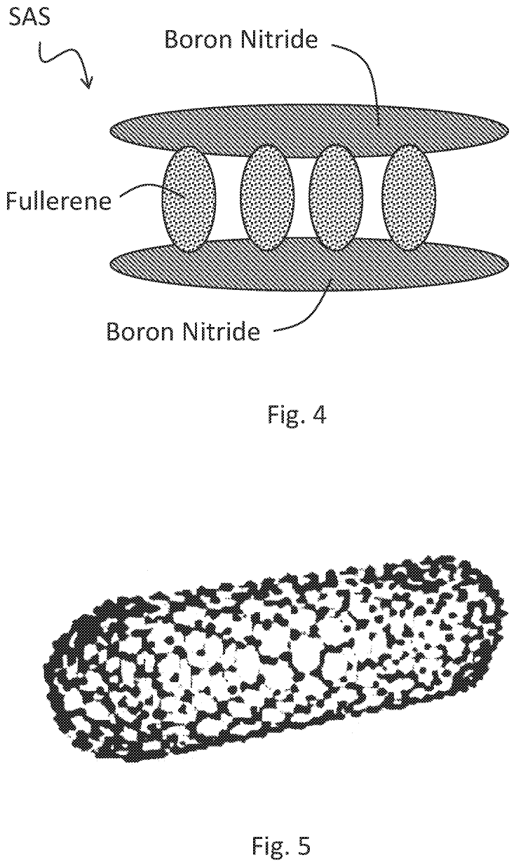

In one embodiment, the aluminum oxide-boron nitride-fullerene composite material includes plural micro-composite particles CMP (FIG. 3 showing schematic cross-section view of the micro-composite particle CMP). In each of the micro-composite particles CMP, the aluminum oxide is disposed at the center of the micro-composite particle CMP, and encircled by a number of the sandwich structures SAS (the number of the sandwich structures SAS in the drawing is only illustrative). Each of the sandwich structures SAS is formed in a sequence (composition disposition sequence) of boron nitride, fullerene, and boron nitride, in which the sides of the sandwich structures SAS facing the aluminum oxide dispose the boron nitrides (referring to FIG. 4). The fullerene may have different disposition directions: a longitude direction, defining the longest scale of a long capsule-like shape of the fullerene, is different from a latitude direction, which defines the shortest scale of the long capsule-like shape of the fullerene. In the sandwich structures SAS, the fullerenes are disposed between the two boron nitrides, and the number of fullerenes shown in the drawings is only illustrative. The composite material can be made by combining various materials in a physical or chemical way. The fullerene of the present invention has a C60 molecular formula (a molecular structure composed of sixty carbon atoms). The fullerenes applied in the present invention have a long capsule-like molecular structure. In FIG. 5, the bold black dots denote the carbon atoms, which are different from the traditional spherical molecular structure of the fullerene, wherein the carbon atoms are distributed on the surface of the spherical shape. The fullerene in the long capsule-like shape has an excellent performance of thermal radiation and electrical conductivity. In the sandwich structures SAS, the two boron nitrides surround the fullerenes, to isolate the conductivity between the fullerenes of the same sandwich structure SAS, and the fullerenes of the different sandwich structures SAS. Therefore, the sandwich structures SAS have excellent thermal radiation capability and electrical isolation property. Therein, the capsule-shaped fullerene applied in the current invention has a high surface emissivity of 0.98 (ε denotes the surface emissivity in the aforementioned thermal radiation formula).

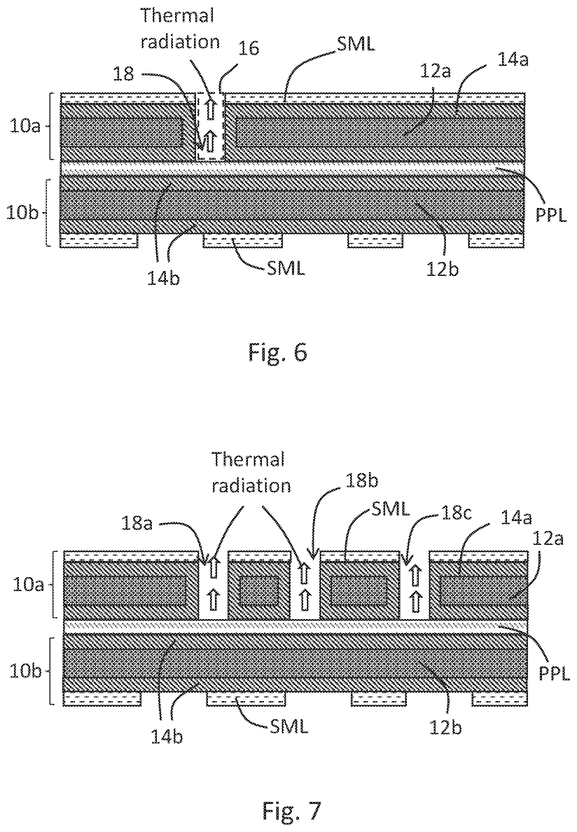

In one embodiment of the sandwich structures SAS (FIGS. 6 and 7), the boron nitrides and fullerenes in the sandwich structure SAS can attract each other due to I-n interaction between the boron nitrides and the fullerenes. For example, a π-π bond interaction occurs between the n electron clouds on the surfaces of the fullerenes and the n electron clouds on the surfaces of the boron nitrides, whereby the fullerenes and the boron nitrides attract each other and connect to each other in the sandwich structures SAS. In one embodiment, the fullerenes can be functionalized to form hydroxyl groups, and the boron nitrides can be functionalized to form hydroxyl-functionalized boron atoms with hydroxyl groups (B—OH) on the surfaces of the boron nitrides. The Fullerenes and the boron nitrides are attracted to connect each other due to hydrogen bonds between the hydroxyl groups of the fullerenes and the boron nitrides. In addition, the aluminum atoms are respectively functionalized to become functionalized aluminum atoms with hydroxyl groups (Al—OH) on the surfaces of the aluminum oxide. This aluminum-hydroxyl group and the boron-hydroxyl group are connected by Hydrogen bonds, which attract and connect each other in the micro-composite particle CMP. The interconnected boron nitrides and fullerenes in the sandwich structure SAS, and the interconnected aluminum oxide and sandwich structure SAS in the composite particle CMP, can be constituted by some known manufacturing processes such as liquid arc (electric arc in liquid). Thus, the aluminum oxide-boron nitride-fullerene composite material in this case is feasible for production, and has excellent electrical insulation and heat transfer capabilities.

In one embodiment, the micro-composite particle CMP has a preferred particle size ranging between 0.01 μm and 60 μm, wherein the micro-composite particles CMP are very small, to exert minimal influence on the manufacturing processes of the solder mask layer SML and the adhesive insulation layer PPL. In the blending process, the melting characteristics change caused by the micro-composite particles CMP can be limited. The manufacturing processes and instruments for the PCB structures of the present invention only need limited adjustment, to finish the composition of the solder mask layer SML and the adhesive insulation layer PPL. Besides, even after a blending process with the aluminum oxide-boron nitride-fullerene composite material, the solder mask layer SML remains compatible with conventional manufacturing process of heat curing, photo curing (e.g., UV curing), and so on.

In one embodiment, the first substrate 10a includes a thermal radiation penetration design, wherein the composition of the adhesive insulation layer PPL includes the aluminum oxide-boron nitride-fullerene composite material. The composition of the first primer material 12a includes a high thermal radiation penetration material, and the thermal radiation from the adhesive insulation layer PPL can pass the first primer material 12a, to achieve heat dissipation effect. Alternatively, on the first substrate 10a, a thermal radiation-permeable section 16 (e.g., through-holes 18 in FIG. 6) provides effective heat dissipation through the first substrate 10a.

The foregoing embodiment is illustrated with the first substrate 10a as an example. The second primer material 12b can have a similar design to the first substrate 10a, wherein the thermal radiation from the adhesive insulation layer PPL can pass through the second substrate 10b to the outside of the PCB structure 100.

In one embodiment, the thermal radiation-permeable section 16 has plural through-holes 18, in the first electronic conductive layer 14a and the first substrate 10a. The thermal radiation generated by the adhesive insulation layer PPL may penetrate the through-holes 18 into the outside of the PCB structure 100.

There can be various feasible designs of the through-holes 18 according to the present invention. In one embodiment, the through-holes 18 include an interconnection structure between the through-holes 18 (interconnected through-holes 18), or a matrix of the through-holes (e.g., the through-holes 18a, 18b, and 18c in FIG. 7) to afford the thermal radiation penetration. For example, when the circuit board design is available, the thermal radiation from the insulating adhesive insulation layer PPL can be transmitted to the outside of the PCB structure 100 through a wider range of the interconnected through-holes 18 in the first substrate 10a. Alternatively, when the wiring on the circuit board is crowded, the thermal radiation from the adhesive insulation layer PPL, can be transmitted through a matrix of the smaller through-holes (18a, 18b and 18c).

Besides, the first substrate 10a of the present invention may also have other designs of the thermal radiation penetrating sections: for example, the first primer material 12a is substantially made of a high thermal radiation transmissive material; or, the first primer material 12a is substantially made of a high thermal radiation transmissive material partially with a void portion of the first electronic conductive layer 14a, to form the thermal radiation penetrating sections.

In one embodiment, with the aluminum oxide-boron nitride-fullerene composite material, a thermal radiation capability of the solder mask layer SML or the adhesive insulation layer PPL, is higher than the substrate 10.

In one embodiment, the composition of the primer material 12 includes epoxy resin, a fiberglass nonwoven material, polyester fiber, bake lite, or polyester material.

In one embodiment, a weight ratio of the aluminum oxide-boron nitride-fullerene composite material in at least one of the compositions of the solder mask layer SML and the adhesive insulation layer PPL, preferably ranges between 2% and 30%, with an optimal weight ratio being substantially 10%.

According to the preliminary experiments by the applicant, when the solder mask layer SML or the adhesive insulation layer PPL includes the aluminum oxide-boron nitride-fullerene composite material, the PCB structure at room temperature has a significant temperature reduction of 3 to 10 degrees Celsius, especially with more obvious temperature reduction effect for the high-temperature components. Therefore, the current invention has the practical effect of enhancing heat dissipation effect.

The above disclosure provides different features in embodiments or examples for implementing the present invention. The examples of components and configurations are described above by illustrating the implementations of the present invention. Of course, these components and configurations are for illustrative purposes only and not intended to limit the scope of the present invention. In addition, some embodiments of the present invention may include repeated reference symbols and/or marks. This repetition is for simplicity and clarity purposes, and does not confine any implementation between the various embodiments and/or configurations.

Further, those who have common knowledge in the art to which the present invention belongs, may make modifications and embellishments without departing from the scope of the present invention, which can be defined according to the claims of the present invention.

What is claimed is:

1. A PCB structure with heat dissipation function, including:
at least one substrate, including a first substrate which includes a first primer material and a first electronic conductive layer disposed on the first primer material; and
a solder mask layer, disposed on the first electronic conductive layer;
wherein, when the at least one substrate includes the first substrate and a second substrate, the PCB structure further includes an adhesive insulation layer disposed between the first substrate and the second substrate; and
wherein, at least one of the material compositions of the solder mask layer and the adhesive insulation layer, includes an aluminum oxide-boron nitride-fullerene composite material, to transmit heat from the substrate into the outside of the substrate by radiation heat transfer.

2. The PCB structure with heat dissipation function according to claim 1, wherein the first electronic conductive layer covers a top surface of the first primer material, or the first electronic conductive layer covers the top surface and a bottom surface of the first primer material opposite to the top surface, wherein the solder mask layer covers the first electronic conductive layer.

3. The PCB structure with heat dissipation function according to claim 1, wherein the aluminum oxide-boron nitride-fullerene composite material includes plural micro-composite particles, wherein the aluminum oxide is disposed at the center of each of the micro-composite particles and encircled by plural sandwich structures in the micro-composite particle, and each of the sandwich structures is formed in a sequence of boron nitride, fullerene, and boron nitride.

4. The PCB structure with heat dissipation function according to claim 3, wherein the sizes of the micro-composite particles range between 0.01 μm and 60 μm.

5. The PCB structure with heat dissipation function according to claim 1, wherein the fullerene includes a C60 molecular structure in a long capsule-like shape.

6. The PCB structure with heat dissipation function according to claim 1, wherein the material of the adhesive insulation layer includes the aluminum oxide-boron nitride-fullerene composite material, and the first primer material is made of a high thermal radiation transmissive material, wherein the thermal radiation from the adhesive insulation layer penetrates the first primer material; or, the first substrate includes a thermal radiation-permeable section, and the thermal radiation from the adhesive insulation layer passes through the thermal radiation-permeable section.

7. The PCB structure with heat dissipation function according to claim 6, wherein in the thermal radiation-permeable section, the first substrate includes at least one through-hole, and the thermal radiation from the adhesive insulation layer passes the through-holes into the outside of the PCB structure.

8. The PCB structure with heat dissipation function according to claim 7, wherein the through-holes include two interconnected through-holes, or the through-holes are in a disposition formation of a through-hole matrix.

9. The PCB structure with heat dissipation function according to claim 1, wherein the material of the primer material, includes epoxy resin, glass fiber nonwoven, polyester fiber, bake lite, or polyester material.

10. The PCB structure with heat dissipation function according to claim 1, wherein a weight ratio of the aluminum oxide-boron nitride-fullerene composite material in at least one of the compositions of the solder mask layer and the adhesive insulation layer, preferably ranges from 2% to 30%, with an optimal weight ratio being substantially 10%.
